(19) United States
(12) Patent Application Publication
(10) Pub. No.: US 2009/0162968 A1
(43) Pub. Date: Jun. 25, 2009

(54) Method and apparatus for producing a semitransparent photovoltaic module

(76) Inventors: Peter Lechner, Vaterstetten (DE); Walter Psyk, Muenchen (DE)

Correspondence Address: FLYNN THIEL BOUTELL & TANIS, P.C., 2026 RAMBLING ROAD, KALAMAZOO, MI, 49008-1631, US

(21) Appl. No.: 12/317,377

(22) Filed: Dec. 22, 2008

(30) Foreign Application Priority Data
Dec. 22, 2007 (DE) 10 2007 062 620.9

(51) Int. Cl. H01L 31/18; B41J 2/01

(52) U.S. Cl. 438/73; 347/1

(57) ABSTRACT

For producing a semitransparent photovoltaic module (1), the transparent substrate (2) is coated with a transparent front electrode layer (3), a semiconductor layer (4) and a metallic back electrode layer (5) and then partial areas (9) of the semiconductor layer (4) and of the back electrode layer (5) are removed. For this purpose, a stripping compound (14) is applied with an ink-jet printer (15) to the front electrode layer (3) on the areas (9) where the semiconductor layer (4) and the back electrode layer (5) are to be removed. Thereafter, the semiconductor layer (4) and the back electrode layer (5) are deposited on the stripping compound (4). Subsequently, the semiconductor layer (4) and the back electrode layer (5) are removed together with the stripping compound (14) from the front electrode layer (3) to form the translucent partial areas (9).

This invention relates to a method for producing a semitransparent photovoltaic module according to the preamble of claim 1 and to an apparatus for carrying out the method.

Photovoltaic modules have an opaque semiconductor layer and an opaque metallic back electrode layer on the transparent front electrode layer, for example consisting of a transparent electrically conductive metal oxide (TCO), which is deposited on a transparent substrate, such as glass. To make the module semitransparent and thus translucent, the opaque semiconductor layer and back electrode layer are removed in partial areas distributed over the module.

The photovoltaic module generally comprises cells which are series-connected by contact of the back electrode layer of one cell with the front electrode layer of the adjacent cell. For series connection there is formed, among other things, a separating line extending perpendicular to the current flow direction, on which the semiconductor layer and the back electrode layer are removed, so that a further translucent partial area is formed.

For removal of the semiconductor layer and the back electrode layer, laser ablation is known. This involves focusing the laser beam through the substrate glass onto the layer and removing the semiconductor layer and back electrode layer. The disadvantage of this method is that the laser beam removes relatively narrow areas of the semiconductor layer and back electrode layer with a width of only about 50 μm. To thus produce a transmittance of the semitransparency of 10% it is necessary to remove the semiconductor layer and back electrode layer over a length of altogether two kilometers per square meter of module area. At a typical traverse rate of the laser beam relative to the substrate surface of 1 m/s, the processing time is thus at least 2000 s, i.e. extremely long.

Another method provides for producing the translucent partial areas by means of wet or dry chemical etching processes. The disadvantage of this method is that the areas not to be removed must be effectively protected from the etching. In reality this requirement cannot be entirely fulfilled and involves the risk of immediate damage to the photovoltaic module, for example by short circuits, or also problems of long-term reliability during operation of the module.

From EP 500 451 B1 it is already known to apply to the back electrode layer on the areas where the translucent partial areas are to be formed an adhesive paste with which the back electrode layer in said areas is removed by stripping, whereupon the removal of the semiconductor layer in said areas is performed by a wet chemical process with caustic soda solution.

It is the object of the invention to substantially shorten the processing time for producing high-quality semitransparent photovoltaic modules.

This is obtained according to the invention by the method characterized in claim 1. Preferred embodiments of the inventive method are stated in claims 2 to 10. A preferred apparatus for carrying out the inventive method is characterized in claim 11. Preferred embodiments of the apparatus are stated in claims 12 to 15.

According to the inventive method, the transparent substrate, for example a glass plate or plastic film, is first coated with the transparent front electrode layer. Coating with the transparent front electrode layer can be effected for example by glow discharge deposition (PECVD). The front electrode layer preferably consists of TCO (transparent conductive oxide), such as tin oxide, zinc oxide and the like.

Subsequently, a stripping compound is applied with an ink-jet printer to the areas of the front electrode layer where the translucent partial areas of the module are to arise after removal of the semiconductor layer and the opaque back electrode layer.

The “ink” of the inkjet printer consists for example of a dispersion or solution of the stripping compound. It is preferable here to use a volatile solvent as the solvent or dispersant, for example alcohol. In case of a dispersion, the dispersed particles can consist for example of abrasive particles (e.g. dye). The ink should itself be water-soluble for later stripping, e.g. by immersion of the module in water.

After drying of the stripping compound, the semiconductor layer is deposited on the front electrode layer provided with the dry stripping compound.

The semiconductor layer can consist for example of amorphous, nanocrystalline or microcrystalline silicon. The deposition of the semiconductor layer is normally effected at a temperature above 200° C., for example by PECVD or by the so-called “hot wire” method.

After deposition of the semiconductor layer in a vacuum, the substrate with the semiconductor layer deposited thereon is aerated e.g. to atmospheric pressure and cooled e.g. to room temperature. Subsequently there is effected the deposition of the metallic back electrode layer, for example by sputtering.

Thereafter, the semiconductor layer, the back electrode layer and the stripping compound are removed in the area of the stripping compound in order to form the translucent partial areas.

For this purpose, the module can be exposed e.g. to a solvent, for example water, e.g. by immersion. Surprisingly, it has turned out that this causes the stripping compound to be detached from the front electrode layer, and thus the semiconductor layer and the back electrode layer to be removed from the area on the stripping compound, together with the stripping compound.

The penetration of the solvent into the stripping compound through the metallic back electrode layer and semiconductor layer deposited thereon is possibly due to microcracks and similar openings in the back electrode layer and the semiconductor layer. However, the exact process for the surprising penetration of the solvent into the stripping compound encapsulated by the semiconductor layer and back electrode layer is unknown.

As mentioned hereinabove, the “ink” applied with the ink-jet printer may be for example a dispersion of the stripping compound comprising alcohols, resins and organic dyes in e.g. alcohol. However, any other stripping compound can also be used provided it is able to form a thin film upon application with an ink-jet printer. Further, the stripping compound must be temperature-resistant for example at a temperature above 200° C. and vacuum-resistant in order for the semiconductor layer to be applicable for example by PECVD. Further, the stripping compound must then resist the subsequent aeration e.g. to atmospheric pressure and cooling e.g. to room temperature while adhering well to the front electrode layer, without the formation of cracks, since otherwise during the subsequent coating with the semiconductor layer or back electrode layer the semiconductor material or the metal of the back electrode layer can penetrate through the cracks in the stripping compound possibly as far as the front electrode layer, so that unremovable residues of the semiconductor material and of the metal of the back electrode layer adhere to the front electrode layer, which can cause short circuits, apart from the visual impairment.

The translucent partial areas of the module can be configured linearly, being in particular straight linear areas. They can extend in the flow direction of the electric current of the module and/or perpendicular to the current flow direction or in another direction of the module.

The translucent areas can further be provided when the module is formed from a plurality of cells which are series-connected with each other, thereby obtaining a module with higher voltage. The series connection is effected by contact of the back electrode layer of one cell with the front electrode layer of the adjacent cell. For series connection of two adjacent cells there is provided, among other things, a separating line extending perpendicular to the current flow direction and performing the function of electrically separating the back electrode of adjacent cells. Said separating line preferably likewise forms translucent partial areas in that with the ink-jet printer by application of the stripping compound to the front electrode the semiconductor layer and back electrode layer applied thereover are removed.

Further, in the case of a discrete negative pole of the module which likewise has the translucent partial areas parallel to the current flow as well as a translucent separating line of the series connection, it is necessary to form a further separating line in the semiconductor layer, mirror-inverted relative to the separating line of the back electrode layer of the series connection. Without this additional separating line in the semiconductor layer, the module would not have a negative pole. An electrical contacting through the separating lines extending e.g. parallel to the current sense, which has the electrical minus potential of the cell adjoining said negative pole, is an alternative possibility for tapping the negative potential of the module. In this case the technically reliable contacting is to be heeded.

If a series connection is provided, there is generally produced between two adjacent cells additionally a further separating line in the front electrode layer, as well as a further parallel separating line offset therefrom in the semiconductor layer. However, said two separating lines are filled with the semiconductor layer or the back electrode layer upon deposition of the semiconductor layer or the back electrode layer. The two further separating lines which extend parallel to the separating line passing through the semiconductor layer and the back contact layer and leading to a translucent partial area can be formed for example by laser ablation.

The translucent partial areas of the inventive transparent module can thus be formed by partial areas within the module or, in the case of a module formed from a plurality of cells, within the cells, and/or by the separating line(s) through the semiconductor layer and the back electrode layer for series connection. The module preferably has both cells with transparent partial areas and transparent separating lines of the series connection. If the transparent partial areas within the cells are formed by straight linear partial areas extending in the flow direction, a visually appealing grid pattern is produced together with the perpendicular transparent separating lines for series connection. The linear transparent partial areas within the cells and the transparent separating lines for series connection can have the same width or be configured with different widths, the transparent separating lines for example being narrower than the transparent lines within the cells or the module.

The thickness of the stripping compound should be, after drying, in the range of the layer thickness of the semiconductor layer, which is preferably 0.1 to 5 μm, in particular 0.3 to 2 μm.

The ink-jet printer used can be for example a so-called continuous ink-jet or CIJ printer or a drop-on-demand or DOD printer.

During printing, the ink-jet printer and the substrate provided with the front electrode layer are moved relative to each other. For this purpose the substrate provided with the front electrode layer can for example be disposed on a slide which is movable in one or two mutually perpendicular directions (e.g. an X/Y coordinate table) and/or the ink-jet printer can be provided on a carrier which is movable in a direction perpendicular to one moving direction of the slide (gantry system). It is also possible to dispose the substrate provided with the front electrode layer on a table, whereby the carrier can be movable relative to the table in two mutually perpendicular directions or only in one direction (split-axis system), whereby the ink-jet printer can then be movable along the carrier.

The ink-jet printer applies to the front electrode layer a pattern of the stripping compound which corresponds to the transparent partial areas of the module or within the cells and/or to the transparent separating lines of the series connection of the cells.

The particle dispersion or solution which is applied to the front electrode layer as “ink” to form the stripping compound must wet the front electrode layer well so as to ensure that the semiconductor layer and back electrode layer applied thereover are stripped without residue. The good wetting at the same time prevents uncontrolled fraying of the stripping compound and thus produces a visually faultless image of the transparent partial areas produced according to the invention.

The stripping compound applied with the ink-jet printer has straight edges or ones that are arched by juxtaposition of discrete drops, depending on the relative speed between the ink-jet printer and the substrate provided with the front electrode layer, and the size of the drops emitted by the ink-jet printer.

The continuous ink-jet printer preferably used can be a single- or multi-jet system. The jet exits from the nozzle through a piezoelectric transducer in single drops, which can be electrostatically charged with charging electrodes and deflected laterally with deflecting electrodes.

It is thus possible to form with the inkjet printer one or more adjoining tracks from the stripping compound. The tracks can overlap or be disposed at a space apart. It is thus possible to apply the stripping compound with a travel motion with a width of for example 100 to 300 μm in the case of one track and with a width of e.g. 200 to 600 μm in the case of two mutually touching tracks, and thus to produce a linear transparent partial area of corresponding width, whereby linear transparent partial areas with an even greater width can be obtained in the case of two spaced-apart tracks of stripping compound.

The wetting of the front electrode with stripping compound in the case of crossing lines is a special characteristic. In the case of crossing ink lines, the second line can be constricted in the area of the intersection point. This constriction can be up to approx. 50% of the line width. It is important here to keep to the order, namely to apply to the front electrode first the stripping compound for the separating grooves of the series connection and then the stripping compound for the separating grooves parallel to the current flow. This order can ensure the electrical separation of the back electrode in defined and reproducible fashion.

This means that if the width of the applied stripping compound line is approx. 250 μm in the case of a module sized one square meter, the processing time is reduced over the laser method stated at the outset for example by a factor of 5 from 2000 seconds to 400 seconds, or in the case of a stripping compound line approx. 500 μm wide, to 200 seconds.

The invention will hereinafter be explained in more detail by way of example with reference to the drawing. Therein is shown schematically:

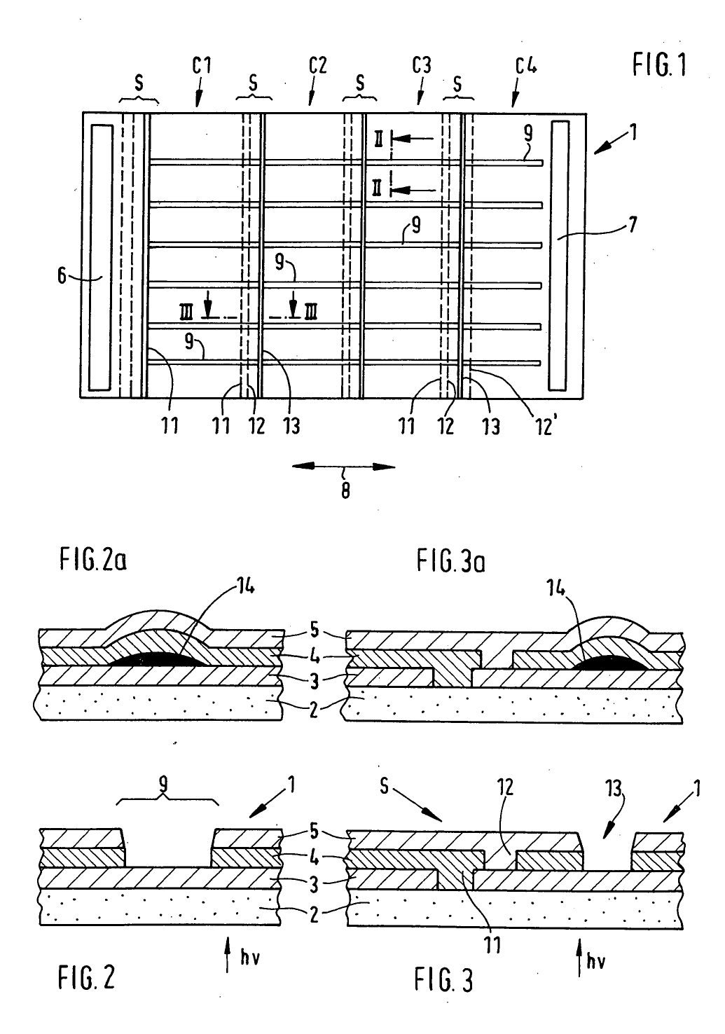

FIG. 1 a view of a semitransparent photovoltaic module from the rear side;

FIG. 2 a section along the line II-II in FIG. 1 in an enlarged view;

FIG. 2a a view corresponding to FIG. 2 prior to removal of the stripping compound and the semiconductor layer and back electrode layer deposited thereon;

FIG. 3 a section along the line III-III in FIG. 1 in an enlarged view;

FIG. 3a a view corresponding to FIG. 3 prior to removal of the stripping compound and the semiconductor layer and back electrode layer deposited thereon;

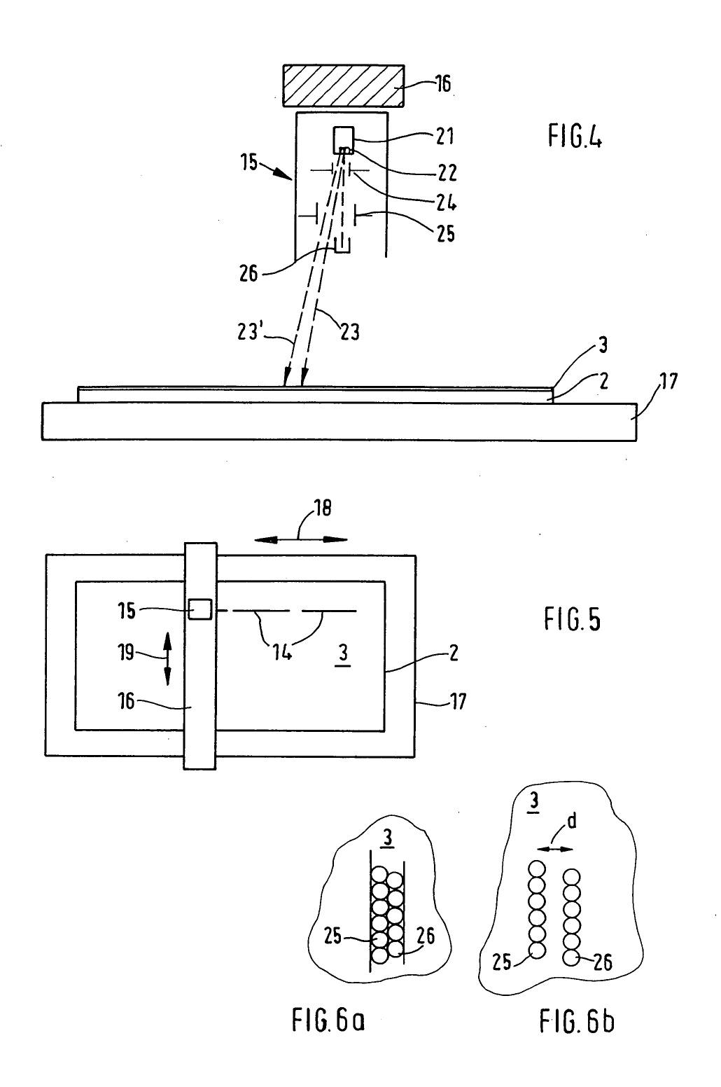

FIGS. 4 and 5 the side view and reduced plan view of an apparatus for applying the stripping compound to the substrate provided with the front electrode layer; and

FIGS. 6a and 6b two stripping compound tracks in each case applied to the front electrode with the ink-jet printer.

According to FIGS. 1, 2 and 3 a photovoltaic module 1 has an electrically insulating transparent substrate 2, for example a glass plate, which is disposed on the side of the module 1 hit by the incident light marked with the arrow hv. On the side facing away from the light incidence side hv the substrate 2 is coated with a transparent front electrode layer 3 e.g. consisting of TCO, a semiconductor layer 4 and an opaque metallic back electrode layer 5.

The module 1 comprises a plurality of cells C1 to C4 which are interconnected by a series connection S. At each end of the module 1 there is provided on the back electrode layer 5 a contact zone 6 or 7 for tapping from the photovoltaic module 1 the current which flows in the module 1 from one contact zone 6 or 7 to the other contact zone 7 or 6 in the direction of the arrow 8. The contact zone 6 thus forms the positive pole of the module 1, and the contact zone 7 the negative pole.

Each cell C1 to C4 has a plurality of spaced-apart linear partial areas 9 on which the semiconductor layer 4 and the opaque back electrode layer 5 have been removed according to FIG. 2, thereby making the partial areas 9 translucent. The translucent linear partial areas 9 extend in the current flow direction 8 and are in each case equally spaced perpendicular to the current flow direction 8. The transparent partial areas 9 of the individual cells C1 to C4 are flush with each other.

The module 1 thus acquires a partial or semitransparency which makes it possible to see through the module 1 against the incident light hv comparably to a net curtain.

The series connection S between two adjacent cells C1 to C4 has according to FIG. 3 a separating line 11 filled with the semiconductor layer 4 in the front electrode 3, a separating line 12 filled with the back electrode layer 5 in the semiconductor layer 4, and a separating line 13 formed by removal of the semiconductor layer 4 and the back electrode layer 5, the latter also being recognizable in FIG. 1 while the separating lines 11 and 12 are indicated by dash lines in FIG. 1. The separating lines 13 which extend perpendicular to the translucent partial areas 9 are likewise translucent, thereby further increasing the partial transparency of the module 1.

Further, in the case of a discrete negative pole 7 of the module 1 which likewise has the translucent partial areas 9 parallel to the current flow as well as a translucent separating line 13 of the series connection S, it is necessary to form a further separating line 12′ in the semiconductor layer 4, mirror-inverted relative to the separating line 13 of the back electrode layer 5 of the series connection. Without this additional separating line 12′ in the semiconductor layer 4 the module 1 would not have a negative pole 7. An electrical contacting through the translucent partial areas 9 extending e.g. parallel to the current sense, which has the electrical minus potential of the cell 3 adjoining the cell 4 with said negative pole 7, is an alternative possibility for tapping the negative potential of the module 1. In this case the technically reliable contacting is to be heeded.

It is evident that all or some of the separating lines 13 can also be omitted at the expense of the transparency, in which case it is also possible to omit the separating line 12′.

To form the translucent areas 9 and the translucent separating lines 13, a stripping compound 14 is applied with an ink-jet printer 15 to the substrate 2 provided with the transparent front electrode layer 3 according to FIGS. 4 and 5.

For this purpose, the ink-jet printer 15 can be disposed on a carrier 16 which is movable along the table 17 in the direction of the double arrow 18. The ink-jet printer 15 can moreover be moved along the carrier 16 and thus perpendicular to the table 17 in the direction of the double arrow 19.

It is thus possible, by moving the carrier 16 according to the arrow 18 to the left in the case of a certain position of the ink-jet printer 15 relative to the carrier 16, to apply the stripping compound 14 with the ink-jet printer to the front electrode layer 3 in flush lines disposed one behind the other according to FIG. 5 to form mutually flush linear partial areas 9 on the cells C1 to C4 in each case according to FIG. 1.

On the other hand, the stripping compound 14 is applied by moving the ink-jet printer 15 along the carrier 16 according to the arrow 19 to form the perpendicular separating lines 13.

After application of the stripping compound 14, the semiconductor layer 4 is applied for example by PECVD and the back electrode layer 5 e.g. by sputtering, resulting in the layer structure shown in FIG. 2a and FIG. 3a wherein the stripping compound 14 is covered with the semiconductor layer 4 and the back electrode layer 5. By immersion of the module 1 for example in water, the stripping compound 14 and the area of the semiconductor layer 4 and of the back electrode layer 5 deposited on said stripping compound are removed to form the translucent partial areas 9 and translucent separating lines 13.

According to FIG. 4, the ink-jet printer 15 has behind the nozzle 22 a piezoelectric transducer 21 which electrostatically charges with a charging electrode 24 the stripping compound suspension supplied from a storage vessel (not shown) in the form of drops 23 which can subsequently be deflected laterally with a deflecting electrode 25, as illustrated by the jet 23′.

It is thus possible to apply the stripping compound to the front electrode layer 3 in two mutually overlapping tracks 25, 26 and in two tracks 25, 26 spaced by distance d according to FIGS. 6a and 6b, respectively. The ink-jet printer 15 is configured as a continuous printer, i.e. the drops 23 are also formed in the pauses, for example for loading and unloading the substrates. For this purpose, the drops 23 can be supplied with the deflecting electrode 25 to a collecting vessel 26 on the print head of the ink-jet printer 15, from where they are circulated to the storage vessel (not shown).

1. A method for producing a semitransparent photovoltaic module (1), wherein a transparent substrate (2) is coated with a transparent front electrode layer (3), a semiconductor layer (4) and a metallic back electrode layer (5), whereupon partial areas (9) of the semiconductor layer (4) and of the back electrode layer (5) are removed to form translucent partial areas (9), characterized in that after the coating of the substrate (2) with the front electrode layer (3) a stripping compound (14) is applied to the front electrode layer (3) with an ink-jet printer (15) on the areas where the semiconductor layer (4) and the back electrode layer (5) are to be removed, whereupon the semiconductor layer (4) and the back electrode layer (5) are deposited on the front electrode layer (3) provided with the stripping compound (14), and subsequently the semiconductor layer (4) and the back electrode layer (5) are removed together with the stripping compound (14) from the front electrode layer (3) in the area of the stripping compound (14) to form the translucent partial areas (9).

2. The method for producing a photovoltaic module according to claim 1 which comprises cells (C1 to C4) which are series-connected by contact of the back electrode layer (5) of one cell (C1 to C4) with the front electrode layer (3) of the adjacent cell (C1 to C4), whereby for series connection (S) there is provided a separating line (13) extending perpendicular to the current flow direction (8), on which the semiconductor layer (4) and the back electrode layer (5) are removed, thereby forming a translucent partial area, characterized in that after the coating of the substrate (2) with the front electrode layer (3), the stripping compound (14) is applied to the front electrode layer (3) with the ink-jet printer (15) on the areas where the separating line (13) is to be formed in the semiconductor layer (4) and the back electrode layer (5).

3. The method according to claim 1, characterized in that for forming the stripping compound (14) a dispersion or solution of the stripping compound in a solvent is applied with the ink-jet printer and is subsequently dried.

4. The method according to claim 1, characterized in that for removal of the semiconductor layer (4) and the back electrode layer (5) together with the stripping compound (13) from the front electrode layer (3), the module (1) is exposed to a solvent.

5. The method according to claim 3, characterized in that the stripping compound (14) has, after drying, a layer thickness which is in the range of the layer thickness of the semiconductor layer (4).

6. The method according to claim 1, characterized in that the partial areas (9) on which the semiconductor layer (4) and the back electrode layer (5) are removed are linear areas.

7. The method according to claim 2, characterized in that the linear areas (9) are formed perpendicular to the separating line (13) in the semiconductor layer and the back electrode layer (5) of the series connection (S).

8. The method according to claim 7, characterized in that first the stripping compound (14) for the separating lines (13) of the series connection (S) is applied, and then the stripping compound (14) for the translucent areas (9).

9. The method according to claim 2, characterized in that adjoining tracks (25, 26) of the stripping compound (14) are applied with the ink-jet printer (15).

10. The method according to claim 1, characterized in that in the case of a discrete electrical negative pole (7) with translucent partial areas (9) parallel to the current flow and translucent separating lines (13) of the series connection (S), a second separating line (12′) is formed in the semiconductor layer (4) parallel and mirror-inverted relative to the separating line (13) of the back electrode layer (5) of the series connection (S).

11. An apparatus for producing a photovoltaic module according to claim 1, characterized in that the ink-jet printer (15) and the substrate (2) coated with the front electrode layer (3) are disposed so as to be movable relative to each other.

12. The apparatus according to claim 11, characterized in that the ink-jet printer (15) is fastened to a carrier (16) which is movable at least in one direction (18).

13. The apparatus according to claim 11, characterized in that a slide movable at least in one direction is provided for receiving the substrate coated with the front electrode (3).

14. The apparatus according to claim 11, characterized in that the ink-jet printer (15) is a continuous ink-jet printer which collects the unneeded stripping compound dispersion or solution on the print head and recycles it to the storage vessel.

15. The apparatus according to claim 11, characterized in that the ink-jet printer (15) has charging electrodes (24) for electrostatically charging, and deflecting electrodes (25) for laterally deflecting, the drops (23) of stripping compound dispersion or solution exiting from the nozzle (22).
